(19) United States
(12) Patent Application Publication
(10) Pub. No.: US 2026/0362590 A1
(43) Pub. Date: Nov. 12, 2026

(54) 25 GBPS SWITCH USING PASSIVE COMPONENTS

(71) Applicant: Raytheon Company, Arlington, VA (US)

(72) Inventors: Robert H. Zurbuch, FORT WAYNE, IN (US); Kyle Grout, MCKINNEY, TX (US); Thanh T. Tran, Houston, TX (US); Brett J. Karns, MCKINNEY, TX (US)

(21) Appl. No.: 19/202,879

(22) Filed: May 8, 2025

(51) Int. Cl. H05K 1/02; H05K 1/11; H05K 1/16

(52) U.S. Cl. CPC H05K 1/029; H05K 1/0224; H05K 1/025; H05K 1/111; H05K 1/162; H05K 1/167

(57) ABSTRACT

A passive switching circuit for high-speed signal routing in space-constrained electronic systems is described. The passive switch includes multiple resistors or capacitors arranged to selectively route 25 Gbps differential signals between connection points on a printed circuit board. The resistors or capacitors are placed in series with shared landing pads to minimize impedance mismatches. Unused signal paths are grounded to prevent noise coupling to active paths. Separate ground vias for configuring resistors or capacitors avoid current sharing between signal paths, reducing interference. The switch enables configurable signal routing between multiple endpoints or any of the endpoints to an external test equipment without requiring active switching components. By selectively populating specific resistors or capacitors during assembly, different routing configurations can be implemented on the same physical board design while maintaining signal integrity at 25 Gbps speeds.

### FIELD

The subject matter disclosed herein relates to circuit card assemblies. In particular, the subject matter disclosed herein relates to high-speed circuit card assemblies operating at least 25 gigabits per second (Gbps).

### BACKGROUND

High-speed digital signal routing in electronic systems presents significant challenges, particularly in environments with space constraints. As data rates increase to 25 Gbps and beyond, traditional signal routing approaches face limitations due to signal integrity concerns. Circuit card assembly designs that support multiple communication channels at such data rates further should maintain signal quality while minimizing electromagnetic interference and impedance mismatches.

In avionics and other specialized electronic systems, printed circuit board (PCB) designs are designed to accommodate numerous interconnections between components while adhering to strict space allocations. The physical layout of circuit traces, vias, and ground planes becomes increasingly important at higher frequencies, as signal degradation can occur due to reflections, crosstalk, and other electromagnetic effects. Traditional high-speed circuit card assembly designs for high-speed signals typically involve active components that use significant amount of power and accordingly generate heat. These components occupy valuable board space and add complexity to the overall system design. It is thus desirable to design a high-speed circuit card assembly design that maintains signal integrity while meeting the relatively severe physical constraints found in avionic systems.

### BRIEF DESCRIPTION OF THE FIGURES

In the figures, which are not necessarily drawn to scale, like numerals may describe similar components in different views. Like numerals having different letter suffixes may represent different instances of similar components. The figures illustrate generally, by way of example, but not by way of limitation, various embodiments discussed in the present document.

FIG. 1 illustrates an aircraft containing an avionics system, according to some examples.

FIG. 2A is a PCB layout illustrating a passive switch circuit with configuration options, according to some examples.

FIGS. 2B and 2C are a PCB layout and schematic diagram, respectively, illustrating the passive switch circuit in a first configuration, according to some examples. Signal flow direction and DC isolation can be configured per the table in FIG. 2D.

FIGS. 2E and 2F are a PCB layout diagram and schematic diagram, respectively, illustrating the passive switch circuit in a second configuration, according to some examples. Signal flow direction and DC isolation can be configured per the table in FIG. 2G.

FIG. 3 is a system diagram showing a view of a 25 Gbps passive switch implementation in an avionics circuit card assembly environment, according to some examples.

FIG. 4 illustrates a block diagram of an electronic device, according to some examples.

FIG. 5 is a flowchart illustrating a method for configuring a passive 25 Gbps switch in space-constrained avionics systems, according to some examples.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

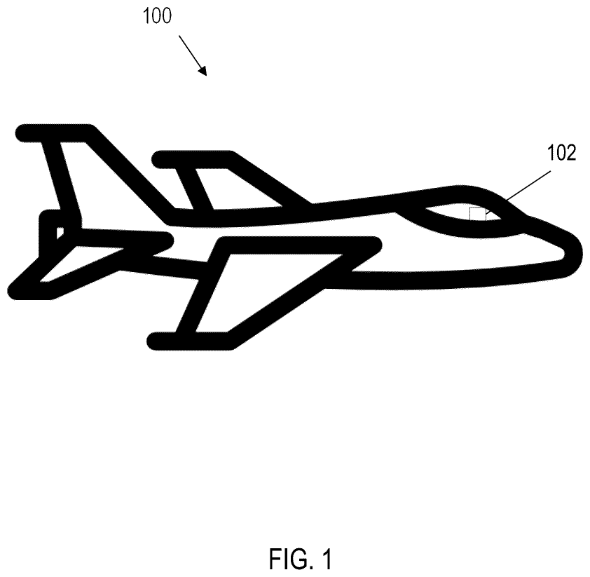

FIG. 1 illustrates an aircraft containing an avionics system in accordance with some embodiments. The aircraft 100 includes avionics systems 102, which refers to the electronic systems used in aircraft, spacecraft, and satellites. These systems encompass communications, navigation, monitoring, flight control, collision avoidance, and various other critical functions. The avionics systems include flight control systems, navigation systems, communication systems, and monitoring systems, for example. The flight control systems may include fly-by-wire systems that replace conventional manual controls, flight management computers that automate navigation and engine controls, and autopilot systems for maintaining flight parameter. The navigation systems may include Inertial Navigation Systems (INS), Global Positioning Systems (GPS), VHF Omnidirectional Range (VOR), Distance Measuring Equipment (DME), and Instrument Landing Systems (ILS). The communication systems may include VHF/UHF radios for air-to-ground communication, satellite communication systems, Aircraft Communications Addressing and Reporting System (ACARS), and data link systems that enable digital information exchange between aircraft and ground stations, as well as between aircraft (e.g., Controller-Pilot Data Link Communications (CPDLC) and Automatic Dependent Surveillance-Broadcast (ADS-B)). The monitoring systems may include Engine Indication and Crew Alerting System (EICAS), Electronic Flight Instrument System (EFIS), Health and Usage Monitoring Systems (HUMS), and flight data recorders.

Avionics systems employ specialized circuitry designed to provide aerospace applications. This circuitry may include Application-Specific Integrated Circuits (ASICs), Field-Programmable Gate Arrays (FPGAs), System-on-Chip (SoC) designs, among others. The ASICs may, for example, in addition to being custom designed for specific avionics functions, be optimized for size, weight, and power (SWaP) requirements within the aircraft 100. ASIC examples include dedicated radar signal processors and flight control computers. FPGAs may be reconfigurable circuits that are used in display systems, navigation processors, and communication interfaces. The circuitry may be high-reliability, radiation-hardened, and include Triple Modular Redundancy (TMR) circuits for critical systems and watchdog timer circuits to detect and recover from system anomalies. Power Management Circuits (PMCs) in the avionic systems may include voltage regulators designed for wide temperature ranges, power sequencing circuits for proper system startup/shutdown, and isolation circuits to prevent fault propagation between systems. Interface circuits may include ARINC 429/629 bus transceivers for avionics data exchange, MIL-STD-1553 interface circuits for military aircraft, and CAN bus and Ethernet PHY circuits for networked avionics. Sensor interface circuits may include signal conditioning circuits for various aircraft sensors, high precision analog-to-digital converters (ADCs) and digital-to-analog converters (DACs).

The circuitry and circuit card assembly of avionics systems 102 may be designed to withstand temperature extremes (−55 °C to +125 °C), vibration and mechanical shock, Electromagnetic Interference (EMI), and large changes in atmospheric pressure, humidity, and moisture. The circuitry and circuit card assembly of avionics systems 102 may include dual or triple redundant processing channels, cross-channel data comparison circuits, and voting logic for fault tolerance, as well as Built-In Test (BIT) Circuitry to provide continuous monitoring circuits for system health and that include self-test circuits that run during startup and operation and fault detection and isolation circuits

As above, circuit designs that are configured to operate at high data rates (at least 25 Gbps) involve a number of design considerations. These considerations only become more difficult in space-constrained environments. For example, high-speed circuit card assembly designs may use active radio frequency (RF) switching components to configure different data paths. These active components use a substantial amount of power, generate heat, and occupy significant board space. Moreover, the space constraints in certain space-constrained environments, such as avionics applications, make the use of such active components impractical. Active RF switches for high-speed signals can be relatively large and may use multiple components for differential signals. For example, a single-ended RF switch include at least two components to handle a differential pair, and additional components are used to handle multiple signal paths. However, there is insufficient room to accommodate active devices when implementing high-speed circuit card assemblies in avionics systems 102. Such embodiments include circuit card assemblies with high component density.

To overcome this issue, a passive switch implementation described herein addresses this by utilizing strategically placed resistors or capacitors and optimized PCB design techniques. The passive resistor or capacitor-based solution occupies less space on the PCB than equivalent active switches. The resistors or capacitors used may be standard surface-mount components with small footprints, such as 0603 or 0402 packages. The entire switching function can be implemented with just a few resistors or capacitors and an appropriate PCB layout. By configuring resistors or capacitors in specific patterns (in series with shared landing pads), the design enables at least 25 Gbps data signal transmissions between different paths while maintaining signal integrity and providing DC isolation if desired. This approach allows for the routing of high-speed signals between different components in a circuit card assembly while maintaining signal integrity, providing impedance matching, noise reduction, and electromagnetic interference mitigation, all achieved without the space and power requirements of traditional active switching solutions.

In particular, the configuration includes multiple resistor or capacitor positions that can be selectively populated to create different signal paths. In some examples, resistors are used to create conductive paths, while unpopulated positions effectively create open circuits. This selective population allows the same physical board design to support multiple signal routing configurations. The resistors may be effectively zero-ohm resistors (i.e., shorts) or may have a minimal resistance (e.g., less than 10 ohms, less than 5 ohms, less than 1 ohm). The capacitors may be in the range of 100 nF to 220 nF to provide DC isolation between the transmitter and receiver.

The design involves the strategic grounding of unused channels. When a particular signal path is not in use, the signal path is grounded to prevent unwanted noise coupling to the active signal paths. This grounding scheme helps maintain signal integrity in the selected paths. The design also incorporates separate ground vias for the configuring resistors or capacitors. This separation avoids current sharing between different signal paths, which reduces interference. The ground vias are strategically placed to minimize electromagnetic radiation that could affect signal quality.

In some examples, the passive switch connects a common input to one of two possible outputs. The configuration determines whether the input connects to the first output while the second output is grounded, or whether the input connects to the second output while the first output is grounded. The implementation includes consideration of the PCB layout; the resistor landing pads are designed to maintain consistent impedance throughout the signal path. This consistency preserves signal integrity at 25 Gbps data rates.

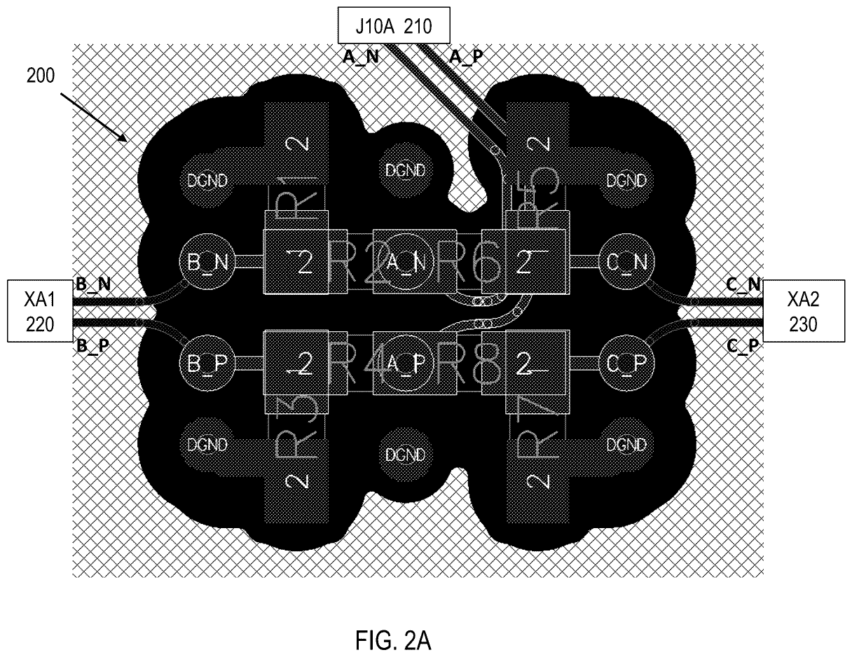

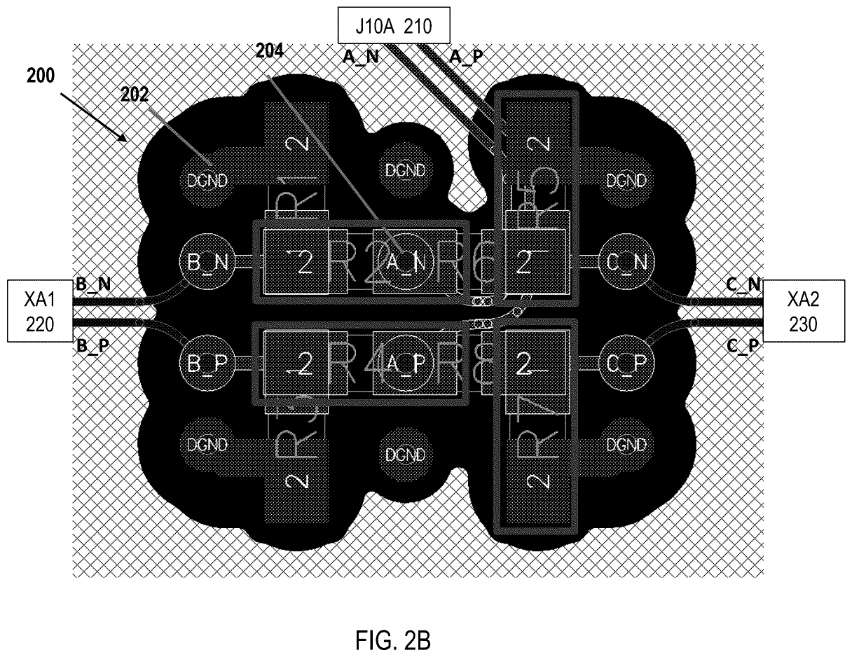

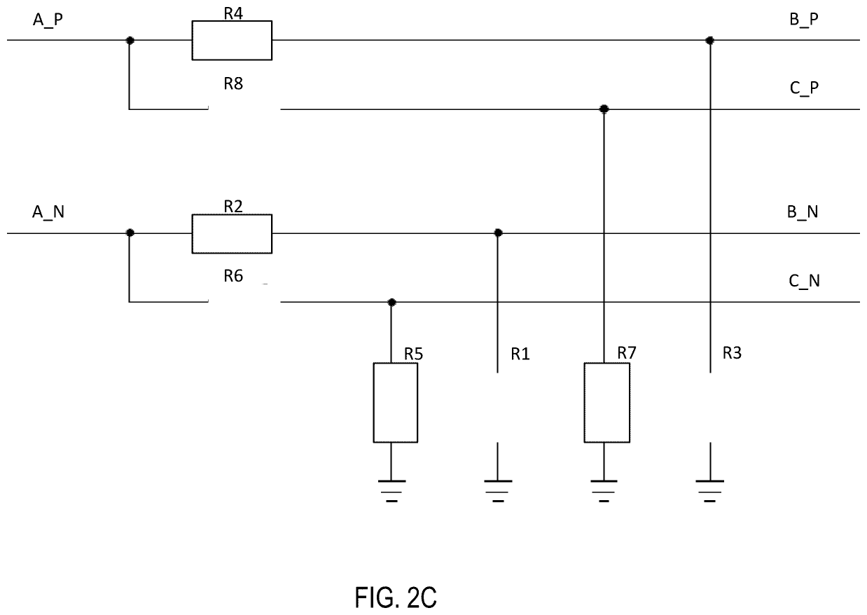

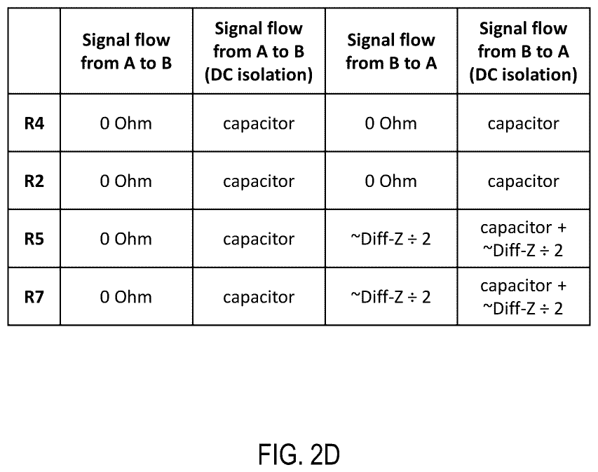

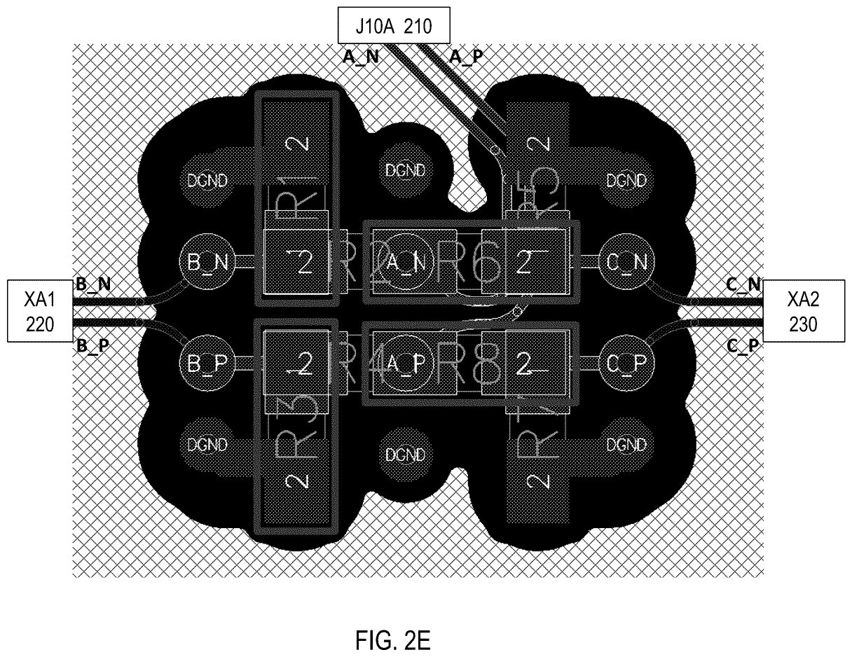

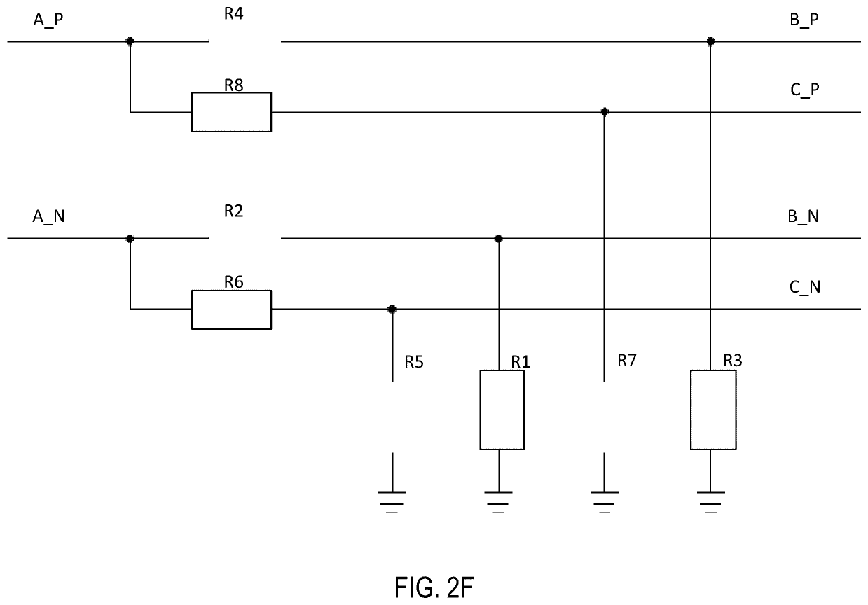

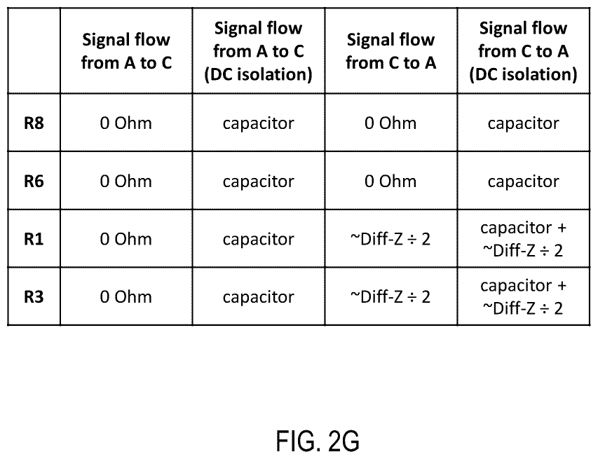

FIG. 2A is a PCB layout showing a functional view of a passive switch circuit, according to some examples. The diagram illustrates a resistor or capacitor-based switching configuration that enables selective routing of high-speed signals between multiple connection points that lead to external circuitry (i.e., circuitry that is external to the passive switch circuit, such as a transmitter, receiver, FPGA, etc.). By changing which resistors or capacitors are populated during assembly or swapped out in the field if desired, the circuit can be configured to route signals between different pairs of connectors.

The passive switch circuit 200 includes multiple resistors and/or capacitors (R1-R8) arranged in a specific configuration to enable signal routing between three connection points. These connection points may be coupled to different connectors, including a J10A connector 210, an XA1 connector 220, and an XA2 connector 230. The resistors and/or capacitors are strategically placed in series with shared landing pads to minimize impedance mismatches that could degrade signal quality at 25 Gbps speeds.

A shared landing pad refers to a single conductive pad that is designed to accommodate multiple resistors or capacitors in different positions on the passive switch circuit 200, although only one resistor or capacitor is populated at a time. This arrangement allows the same physical board design to support multiple signal routing configurations without redesign. The shared landing pad design maintains signal integrity at 25 Gbps speeds because the shared landing pad design minimizes impedance discontinuities that may otherwise occur if separate, non-overlapping pads were used for each possible resistor or capacitor position. By sharing landing pads, the design maintains consistent impedance throughout the signal path regardless of which configuration is implemented.

The passive switch circuit 200 includes multiple resistor or capacitor positions that may be selectively populated to create different signal paths. In some examples, resistors or capacitors are used to create conductive paths, while unpopulated positions effectively create open circuits. This selective population allows the same physical board design to support multiple signal routing configurations without requiring active switching components. As above, the resistors may be zero-ohm resistors or may have minimal resistance, and the capacitors may be in the range of 100 nF to 220 nF.

The resistors are arranged such that R2, R4, R6, and R8 when present connect to the J10A connector 210, R1-R4 when present connect to the XA1 connector 220, and R5-R8 when present connect to the XA2 connector 230.

FIGS. 2B and 2C are a PCB layout and circuit diagram, respectively, illustrating the passive switch circuit in a first configuration, according to some examples. In the first configuration, the resistors R2, R4, R5, and R7 (shown by the thick boarders in FIG. 2B) of the passive switch circuit 200 are populated with resistors, while resistors R1, R3, R6, and R8 are left unpopulated. This configuration establishes a signal path between the J10A connector 210 and the XA1 connector 220, while the XA2 connector 230 is effectively grounded to prevent unwanted noise coupling. In particular, as shown in the circuit diagram of FIG. 2C, A_N is connected to B_N through R2, A_P is connected to B_P through R4, and C_N and C_P are grounded respectively through R5 and R7. In some embodiments, the resistors may instead be implemented using capacitors if DC isolation is desired. Signal flow direction and DC isolation can be configured per the table in FIG. 2D.

FIGS. 2E and 2F are a PCB layout diagram and schematic diagram, respectively, illustrating the passive switch circuit in a second configuration, according to some examples. Signal flow direction and DC isolation can be configured per the table in FIG. 2G. In the second configuration, resistors R1, R3, R6, and R8 (shown by the thick boarders in FIG. 2D) are populated with resistors, while resistors R2, R4, R5, and R7 are left unpopulated. This configuration establishes a signal path between the J10A connector 210 and the XA2 connector 230, while the XA1 connector 220 is effectively grounded to prevent unwanted noise coupling. In particular, as shown in the circuit diagram of FIG. 2E, A_N is connected to C_N through R6, A_P is connected to C_P through R8, and B_N and B_P are grounded respectively through R1 and R3. As above, in some embodiments, the resistors may instead be implemented using capacitors if DC isolation is desired. Signal flow direction and DC isolation can be configured per the table in FIG. 2G.

The passive switch circuit 200 includes separate ground vias 202 for the configuring resistors. These separate ground vias 202 avoid current sharing between different signal paths, which reduces interference. The ground vias 202 are strategically placed around the passive switch circuit 200 to minimize electromagnetic radiation that could affect signal quality. As shown, the ground vias 202 are disposed along the outer edge of the passive switch circuit 200, essentially encircling the resistor or capacitor landing pads 204 to which the resistors or capacitors make contact. The placement of the ground vias 202 includes placing the ground vias 202 at the corners of the passive switch circuit 200 and the sides of the passive switch circuit 200 between at least some of the corners. The landing pads 204 are arranged such that some of the landing pads 204 serve multiple resistors or capacitors, though only one resistor or capacitor may be populated at each shared position.

The physical implementation of the passive switch circuit 200 includes careful consideration of the PCB layout. The resistor landing pads 204 are designed to maintain consistent impedance throughout the signal path. This consistency preserves signal integrity at 25 Gbps data rates.

The passive switch circuit 200 interfaces with other components in the system through the connectors 210, 220, and 230. These connectors may connect to various devices such as field-programmable gate arrays (FPGAs), graphics processing units (GPUs), or other processing elements in an avionics system.

In some examples, the resistors may have values other than zero ohms to provide impedance matching or signal attenuation. The spacing between resistors and ground planes may be controlled to maintain the differential impedance of throughout the signal path. In one example, the difference may be approximately 100 ohms (such as for an Ethernet), although other impedances may be used, such as 85 ohms for high speed PCIe pairs (65-105 ohms per the PCIe specification). The capacitors may have the value in the range of 100 nF to 220 nF to maintain good signal integrity.

The data structure represented by this diagram supports a one-to-many relationship between the input differential pair A and the two possible output differential pairs B and C. However, only one output path is active at any time, with the inactive path being grounded to prevent signal reflections and interference. In other embodiments, the circuit may be modified using more than one input differential pair and/or more than two possible output differential pairs. In addition, the data structure can also be used in the opposite direction as that shown.

In some examples, a limited number of active devices may be used instead of or in addition to using resistors or capacitors for path selection. For example, various implementations may provide PIN diodes and capacitive coupling between transmission lines rather than direct resistive connections. PIN diodes can function as variable resistors in RF applications and may be biased to provide either a low-impedance path or high-impedance isolation. The use of PIN diodes may allow for electronic control of the switch configuration while maintaining the passive nature of the signal path when the diodes are properly biased. Transmission line stubs with specific lengths may be used to create constructive or destructive interference at specific frequencies, effectively creating a frequency-selective switch. By designing the stub lengths, certain signal paths may be enabled or disabled based on the signal frequency characteristics. Alternatively, or in addition, by controlling the spacing and overlap between adjacent transmission lines, the design may achieve controlled coupling of high-frequency signals while maintaining isolation at lower frequencies. The capacitive coupling approach may be particularly effective for applications where DC isolation between paths is to be considered.

In some other examples, printed inductors and capacitors may be used to create frequency-selective filters that pass or block signals based on their frequency content. By designing the passive filter elements using the considerations herein, the implementation may achieve switching functionality without the use of active components or manually installed resistors. As in the other examples, the printed inductors and capacitors may be used in place of, or in addition to (i.e., in parallel or series with) some of the resistors.

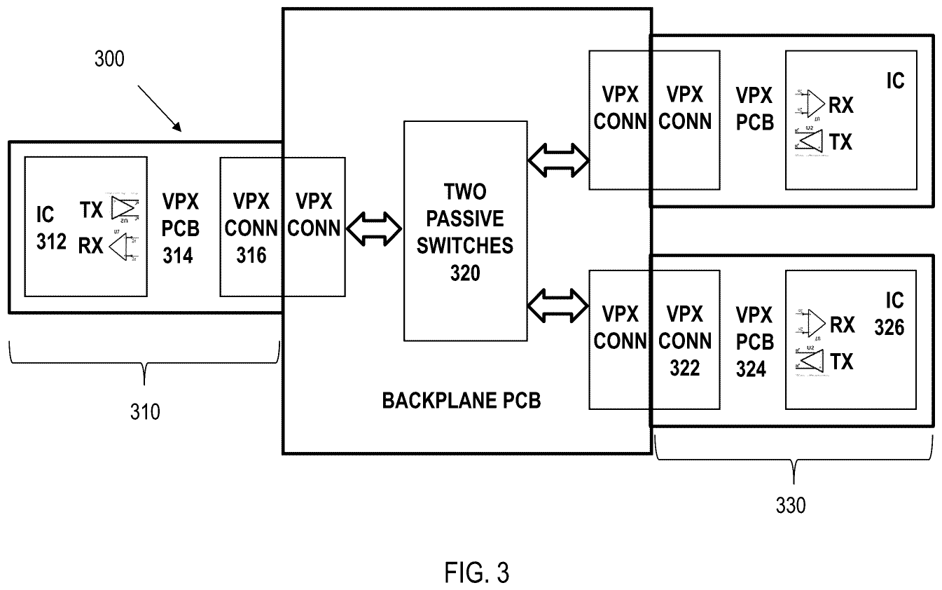

FIG. 3 is a system diagram showing a view of a 25 Gbps passive switch implementation in an avionics circuit card assembly environment, according to some examples. The diagram illustrates the complete signal path between transceivers through the passive resistor or capacitor-based switch circuit.

The system 300 may include a transmitter section 310, a passive switch section 320, and a receiver section 330, all interconnected via high-speed differential signal traces on a printed circuit board. The transmitter section 310 may include an FPGA 312 that generates 25 Gbps differential signals. The FPGA 312 connects to a VPX transmitter module 314 through impedance-controlled traces. The VPX transmitter module 314 interfaces with the circuit card assembly through a VITA connector 316, which may be a TE 40G connector in some examples.

The passive switch section 320 may be similar to that shown in FIG. 2A, including eight (or more) resistors or capacitors arranged in a specific configuration to enable signal routing between multiple connection points. The resistors are strategically placed in series with shared landing pads to minimize impedance mismatches that would degrade signal quality at 25 Gbps speeds.

The receiver section 330 may mirror the transmitter section 310. In this case, the receiver section 330 includes a VITA connector 322 that interfaces with the circuit card assembly, a VPX receiver module 324, and an FPGA 326 that processes the received 25 Gbps signals.

As shown, switches can be used to send data in both directions throughout the system. Additional switches may be added to support more channels.

The signal path through the system 300 may span approximately 13 inches, with the transmitter section 310 and receiver section 330 each measuring 2-3 inches, and the circuit card assembly section measuring approximately 8-9 inches. The entire signal path is designed with controlled impedance to maintain signal integrity at 25 Gbps data rates. The system 300 operates within a larger avionics circuit card assembly environment that may include multiple processing elements such as single board computers (SBCs), GPUs, and Ethernet network switches (ENS). The passive switch section 320 enables flexible routing of 25 Gbps Ethernet signals between these components without using active switching components that would consume additional space, power, and generate heat.

Simulation results for the system 300 demonstrate that the passive switching solution maintains adequate signal quality for 25 Gbps operation. Eye diagrams show sufficient eye width and height margins that exceed the minimum requirements for reliable operation with certain FPGA transceivers. For example, in the first configuration shown in FIG. 2B, the measured eye width is 0.637019 UI (Unit Intervals) and the eye height is 0.27982V. These values translate to an eye width of 25.5 picoseconds and an eye height of 280 millivolts, which exceed the minimum requirements of 8.8 picoseconds and 60 millivolts respectively. Similarly, in the second configuration shown in FIG. 2D, the measured eye width is 0.689904 UI and the eye height is 0.282375V. These values translate to an eye width of 27.6 picoseconds and an eye height of 282 millivolts, again exceeding the minimum requirements.

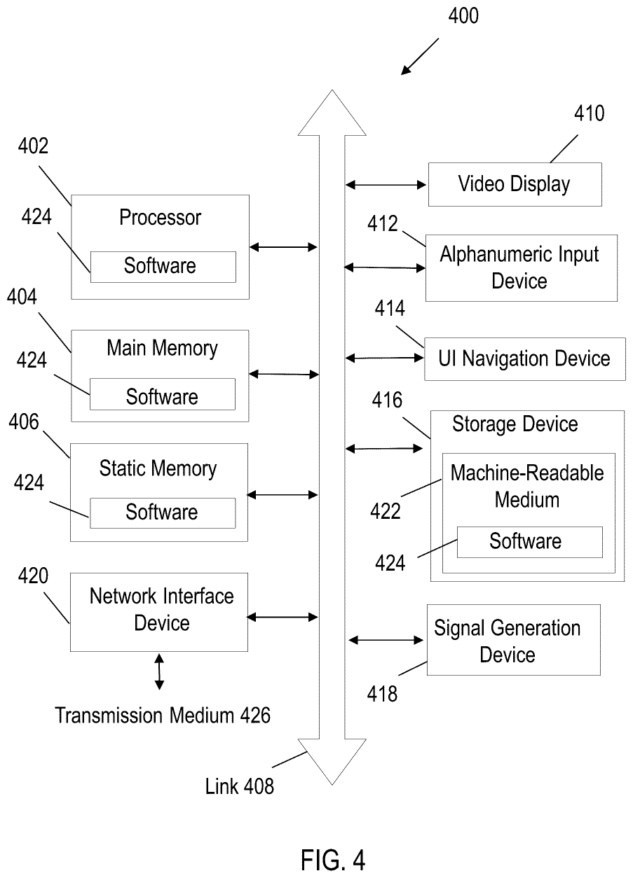

FIG. 4 illustrates a block diagram of an electronic device in accordance with some embodiments. The device 400 may be any electronic device (or circuitry) described herein and may include the passive switch described herein.

Examples, as described herein, may include, or may operate on, logic or a number of components, modules, or mechanisms. Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The device 400 may include some or all the elements shown in FIG. 4, including a hardware processor (or equivalently processing circuitry) 402 (e.g., a CPU, a GPU, a hardware processor core, or any combination thereof), a main memory 404 and a static memory 406, some or all of which may communicate with each other via an interlink (e.g., bus) 408. The main memory 404 may contain any or all of removable storage and non-removable storage, volatile memory or non-volatile memory. The device 400 may further include a display unit 410 such as a video display, an alphanumeric input device 412 (e.g., a keyboard), and a user interface (UI) navigation device 414 (e.g., a mouse). In an example, the display unit 410, input device 412 and UI navigation device 414 may be a touch screen display. The device 400 may additionally include a storage device (e.g., drive unit) 416, a signal generation device 418 (e.g., a speaker), a network interface device 420, and one or more sensors, such as a global positioning system (GPS) sensor, compass, accelerometer, or another sensor. The device 400 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 416 may include a non-transitory machine readable medium 422 (hereinafter simply referred to as machine readable medium) on which is stored one or more sets of data structures or instructions 424 (e.g., software) embodying or utilized by any one or more of the techniques or functions described herein. The non-transitory machine readable medium 422 is a tangible medium. The instructions 424 may also reside, completely or at least partially, within the main memory 404, within static memory 406, and/or within the hardware processor 402 during execution thereof by the device 400. While the machine readable medium 422 is illustrated as a single medium, the term “machine readable medium” may include a single medium or multiple media (e.g., a centralized or distributed database, and/or associated caches and servers) configured to store the one or more instructions 424.

The term “machine readable medium” may include any medium that is capable of storing, encoding, or carrying instructions for execution by the device 400 and that cause the device 400 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 424 may further be transmitted or received over a communications network using a transmission medium 426 via the network interface device 420 utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as IEEE 802.11 family of standards known as Wi-Fi, IEEE 802.16 family of standards known as WiMax, IEEE 802.15.4 family of standards, an LTE family of standards, a UMTS family of standards, peer-to-peer (P2P) networks, a 5G standards among others. In an example, the network interface device 420 may include one or more physical jacks (e.g., Ethernet, coaxial, or phone jacks) or one or more antennas to connect to the transmission medium 426.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single-or multi-core processor, and/or any other device capable of executing or otherwise operating computer-executable instructions, such as program code, software modules, and/or functional processes.

Any of the radio links described herein may operate according to any one or more of radio communication technologies and/or standards. Aspects described herein may be used in the context of any spectrum management scheme including dedicated licensed spectrum, unlicensed spectrum, license exempt spectrum, (licensed) shared spectrum and further frequencies.

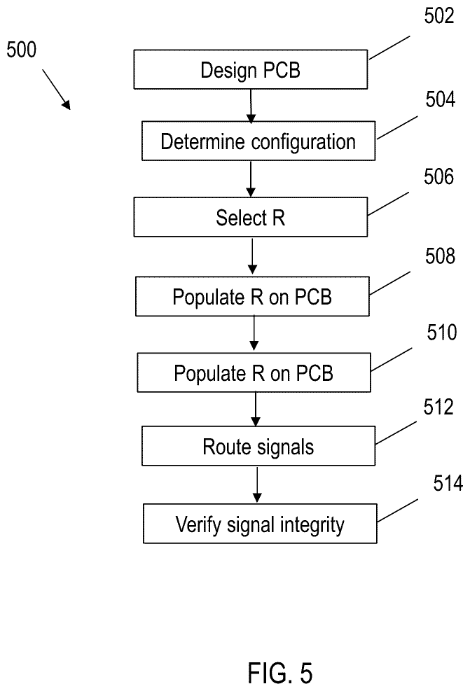

FIG. 5 is a flowchart illustrating a method for configuring a passive 25 Gbps switch, according to some examples, of selectively routing high-speed signals in space-constrained avionics systems. Although the example method 500 depicted in FIG. 5 depicts a particular order of operations, some of the operations may be present, additional operations may be present, or the order of operations may be different from that shown. For example, some of the operations depicted may be performed in parallel. In some examples, different components of an example device or system that implements the method may perform functions at substantially the same time or in a specific sequence.

At block 502, a PCB and passive switch circuit is designed with multiple signal paths and resistor landing pads for a passive switch configuration. The PCB is designed to include ground vias placed to minimize electromagnetic radiation and provide proper signal return paths. The design process may involve trace routing considerations to maintain consistent impedance throughout the signal paths. The PCB may be designed for use in multiple applications that depend on the connections to be formed using the PCB. The spatial limitations and electronic properties (e.g., noise, impedance mismatch, impedance of resistor configurations) for the design within a particular space-constrained system (such as an avionics system) may be

At block 504, the system determines which signal routing configuration is to be used for a specific application to be implemented. This determination may be based on the system architecture requirements, such as whether a connection is to be between a J10A connector and an XA1 connector, or between a J10A connector and an XA2 connector. The determination process may involve analyzing the circuit card assembly layout and the interconnections between various components such as FPGAs, GPUs, or other processing elements.

At block 506, based on the determination in block 504, a specific set of resistors is selected for population on the PCB. The values of the resistors, along with the resulting electrical properties may be stored in a table in a memory of the system used for the design.

At block 508, the selected resistors are populated on the PCB while leaving the unselected resistor positions unpopulated. The population process may involve placing the resistors at the designated landing pads of the PCB to provide the signal paths to route signals through the PCB. The resistors may subsequently be soldered or otherwise attached to the landing pads. The unpopulated positions effectively create open circuits in those signal paths. The resistors may be permanently attached to the landing pads during assembly or may be removably attached so that the resistors are able to be removed and replaced in the field, if desired.

At block 510, the unused signal paths may be grounded through the populated resistors to prevent unwanted noise coupling to the active signal paths. This grounding scheme may help to maintain signal integrity in the selected paths. The separate ground vias for the configuring resistors avoid current sharing between different signal paths to reduce interference.

At block 512, the configured passive switch may be used to route high-speed signals (e.g., at least 25 Gbps) between the selected connection points while maintaining signal integrity. The PCB containing the passive switch with the installed resistors may be installed in the desired system, such as the avionics system, after testing/verification.

At block 514, the system may verify the signal integrity of the configured passive switch. This verification may involve measuring eye diagrams to confirm sufficient eye width and height margins that exceed the minimum requirements for reliable operation. The verification may be performed before block 512, in which case, the configured passive switch may be used to route high-speed signals between the selected connection points after verification. The external test equipment, which may include one or more of a digital oscilloscope, spectrum analyzer or vector network analyzer, can be connected to one of endpoints for testing to avoid adding test points on the printed circuit board. Test points affect signal integrity because of extra stubs and vias added to high-speed signal traces.

Accordingly, the resistors in the passive switch are selectively populated to create specific signal paths for different applications. For avionics applications, the resistor configuration can be customized during assembly based on the specific aircraft's communication requirements. This is particularly valuable in military aircraft where space is extremely limited, but high-speed data transfer is essential between radar systems, mission computers, and display systems. The passive nature of the switch eliminates heat generation concerns in thermally sensitive avionics bays.

In satellite systems where radiation hardening and power conservation are useful, the passive switch is able to route high-speed signals between different subsystems without consuming power or generating heat. The implementation would utilize the resistor configuration shown in the figures, but with radiation-hardened resistors and PCB materials. The ground via placement technique described above may be of particular use to minimize electromagnetic interference in the space environment. The verification process outlined in FIG. 5 may include additional steps for radiation testing to ensure signal integrity is maintained even under radiation exposure.

For reconfigurable computing platforms that are to adapt to different processing configurations, the passive switch can route high-speed signals between various processing elements based on the current computational needs. For example, in one configuration, a GPU may be connected to a memory controller, while another configuration the GPU may be connected to a network interface. In this implementation, the system may be designed with multiple possible configurations that can be selected during assembly or maintenance based on the specific computational requirements of the mission.

In high-density data centers where rack space is limited but high-speed connectivity is a consideration, the passive switch can enable flexible routing of 25 Gbps Ethernet signals without using active switching components that consume space and power. The implementation would scale up the design shown above to accommodate multiple input and output pairs. The resistor placement technique may thus be adapted to handle multiple signal paths while maintaining the signal integrity benefits of the original design.

In medical imaging systems in which electromagnetic interference is to be minimized and reliability is a consideration, the passive switch can route high-speed signals between imaging sensors, processing units, and storage systems. This implementation may utilize the ground via placement technique above to minimize electromagnetic emissions that could interfere with sensitive medical sensors. The resistor configuration may be adapted to provide isolation between critical signal paths. The verification process may include additional steps beyond those shown in FIG. 5 to ensure compliance with medical equipment standards, with particular attention to electromagnetic compatibility testing.

In next-generation vehicles with advanced driver assistance systems (ADAS) and autonomous driving capabilities, the passive switch may be used to route high-speed signals between various sensors, processing units, and control systems. The implementation may adapt the design shown to meet automotive reliability standards, with particular attention to vibration resistance and temperature range. The resistor configuration may enable different routing options based on the vehicle's specific sensor configuration. The verification process would extend beyond the eye diagram analysis to include automotive-specific testing such as temperature cycling, vibration testing, and EMI/EMC compliance verification.

For modular test equipment that is to adapt to different device-under-test configurations, the passive switch can route high-speed signals between various test modules without involving reconfiguration of the entire test system. The implementation would follow the approach above, in which different resistor populations create different signal paths. This may allow test engineers to reconfigure the signal routing by simply changing which resistors are populated, rather than redesigning the entire test fixture. The verification process may incorporate the eye diagram analysis, ensuring that signal integrity is maintained across all possible configurations to prevent false test results due to signal degradation.

In high-performance computing clusters where node-to-node communication speed is a consideration, the passive switch can route high-speed signals between compute nodes, storage nodes, and network interfaces. The implementation may scale up the design to accommodate the higher port count in HPC environments. The resistor placement may be optimized for the specific impedance requirements of the high-performance computing interconnects. The verification process may follow the approach shown in FIG. 5, with particular attention to latency measurements to ensure that the passive switch does not introduce significant delays that would impact computational performance.

The design herein implements a 25 Gbps Ethernet switch that may use only passive resistors and optimized printed circuit board design techniques. This approach allows for switching high-speed 25 Gbps Ethernet channels in space-constrained environments where traditional active switching components cannot be accommodated, while providing the flexibility of the same switch design to be used for different applications by merely adjusting circuitry added to the board during assembly. For example, resistors may be placed in series with shared resistor landing pads to minimize impedance mismatch, unused channels may be grounded to prevent unwanted noise coupling to the selected signal paths, and separate ground vias may be created for the resistors to avoid current sharing and reduce interference. The placement of the ground vias may be strategically designed to minimize electromagnetic radiation. The passive resistor switch configuration provides a smaller footprint and lower power solution compared to traditional active switch implementations.

In particular, the technical design incorporates impedance matching considerations to maintain signal integrity at high data rates. The placement of resistors and vias follows specific patterns to minimize signal reflections and maintain controlled impedance throughout the transmission path. The design accounts for differential pair routing with consistent spacing and reference planes to maintain the differential impedance used in the high-speed connections (e.g., Ethernet, PCIe, USB, SATA, LVDS, and others).

The implementation includes consideration of via structures, with specific attention to via stub length minimization and anti-pad sizing to reduce parasitic capacitance. Ground via placement follows a pattern that creates an effective electromagnetic shield around the high-speed signal paths, reducing emissions and susceptibility to external interference.

The resistor landing pad design incorporates tapered transitions to maintain consistent impedance at the connection points. This approach minimizes discontinuities that could otherwise create signal reflections and degrade the eye pattern at the receiver.

Signal path length matching is implemented with tolerances below 5 mils to ensure proper timing relationships between differential pairs. The design incorporates specific routing rules that maintain minimum bend radii of the signal paths and avoid 90-degree corners in the high-speed traces.

The ground plane design includes specific considerations for return current paths, with stitching vias placed at strategic locations to provide low-impedance return paths for high-frequency components of the signals. This approach reduces common-mode noise and improves electromagnetic compatibility.

In one example, a 68% reduction in PCB area resulted by the use of discrete passive components; the passive circuit used about 0.020 sq. inches, while the multiple active switches (rated for 25 Gbps) that the passive circuit replaced used about 0.062 sq inches. Passive switch routing area used is significantly lower because passive switch components are strategically placed to guarantee reduced loop areas. In the active case, all the signals are routed through the switch, which may cause issues with signal losses, crosstalk, excessive electromagnetic radiation due to larger loop areas, and signal integrity. For 25 Gbps designs, the traces should be kept as short as possible to improve performance.

### EXAMPLES

Example 1 is a printed circuit board (PCB) for use in an avionics system, the PCB comprising: a passive switch circuit having resistor or capacitor positions arranged on a printed circuit board configured to selectively route differential signals of at least 25 Gigabits per second (Gbps) between connection points of external circuitry in the avionics system without use of active elements in the passive switch circuit, wherein the resistor positions are configured to be selectively populated with resistors or capacitors to create different signal paths in different resistor or capacitor configurations and unpopulated resistor or capacitor positions create open circuits in corresponding signal paths dependent on an application to be provided by the passive switch circuit in the avionics system.

In Example 2, the subject matter of Example 1 includes, wherein: the resistor or capacitor positions are arranged with shared landing pads, each shared landing pad is a single conductive pad that is designed to accommodate a resistor or capacitor disposed in different positions on the passive switch circuit to provide the different resistor or capacitor configurations, and the different resistor or capacitor configurations are configured to provide identical impedances.

In Example 3, the subject matter of Example 2 includes, wherein the resistor or capacitor positions are configured such that when populated with resistors or capacitors, unused signal paths are connected to ground and configured to reduce noise coupling to active signal paths.

In Example 4, the subject matter of Example 3 includes, separate ground vias for the populated resistors or capacitors to mitigate current sharing between different signal paths.

In Example 5, the subject matter of Example 4 includes, wherein the ground vias are disposed around the passive switch circuit to minimize electromagnetic radiation, including an outer edge of the passive switch circuit.

In Example 6, the subject matter of Examples 1-5 includes, wherein the resistor or capacitor positions are configured to route signals between a first connector and either a second connector or a third connector dependent on the resistor or capacitor configuration.

In Example 7, the subject matter of Example 6 includes, wherein: in a first configuration, a first set of resistor positions is populated with resistors to establish a signal path between the first connector and the second connector, while the third connector is grounded, and in a second configuration, a second set of resistor positions is populated with resistors to establish a signal path between the first connector and the third connector, while the second connector is grounded.

In Example 8, the subject matter of Examples 1-7 includes, wherein: the resistors comprise zero-ohm resistors, the capacitors comprise 100 nF to 220 nF capacitors, and a resistor or capacitor configuration used in the passive switch circuit is preconfigured and selected during assembly based on the avionics system.

In Example 9, the subject matter of Examples 1-8 includes, wherein the resistors have resistance values selected for at least one of impedance matching or signal attenuation, spacing between resistors and ground planes controlled to maintain a constant differential impedance throughout each signal path.

Example 10 is a method for providing passive switching in an avionics system, the method comprising: providing a printed circuit board (PCB) having a passive switch circuit with resistor or capacitor positions arranged to selectively route differential signals of at least 25 Gigabits per second (Gbps) between connection points without use of active elements in the passive switch circuit; determining a signal routing configuration for the passive switch circuit dependent on an application to be provided by the passive switch circuit in the avionics system; selecting a set of the resistor or capacitor positions for population based on the determined signal routing configuration; and populating the selected resistor or capacitor positions with resistors or capacitors while leaving unselected resistor or capacitor positions unpopulated prior to installation in the avionics system.

In Example 11, the subject matter of Example 10 includes, arranging the resistor or capacitor positions using shared landing pads to minimize impedance mismatches and maintain consistent impedance throughout a signal path regardless of which resistor configuration is implemented, each shared landing pad being a single conductive pad that is designed to accommodate a resistor or capacitor disposed in different positions on the passive switch circuit to provide the different resistor configurations, the different resistor or capacitor configurations configured to provide identical impedances.

In Example 12, the subject matter of Examples 10-11 includes, grounding unused signal paths through the populated resistors or capacitors to prevent unwanted noise coupling to active signal paths.

In Example 13, the subject matter of Example 12 includes, wherein grounding unused signal paths comprises using separate ground vias to minimize electromagnetic radiation and provide signal return paths.

In Example 14, the subject matter of Example 13 includes, wherein the ground vias are disposed around the passive switch circuit to minimize electromagnetic radiation, including an outer edge of the passive switch circuit.

In Example 15, the subject matter of Examples 10-14 includes, wherein: the resistor or capacitor positions are configured to selectively route signals between a first connector and either a second connector or a third connector, in a first configuration, a first set of resistor positions is populated with resistors to establish a signal path between the first connector and the second connector, while the third connector is grounded, and in a second configuration, a second set of resistor positions is populated with resistors to establish a signal path between the first connector and the third connector, while the second connector is grounded.

In Example 16, the subject matter of Examples 10-15 includes, wherein: the resistors comprise zero-ohm resistors, the capacitors comprise 100 nF to 220 nF capacitors, and a resistor or capacitor configuration used in the passive switch circuit is preconfigured and selected during assembly based on the avionics system.

Example 17 is an avionics system comprising: a transmitter comprising a field-programmable gate array (FPGA) that generates high-speed differential signals of at least 25 Gigabits per second (Gbps); a receiver comprising an FPGA that processes received high-speed differential signals; and a passive switch circuit connecting the transmitter and the receiver, the passive switch circuit having resistor or capacitor positions configured to route the high-speed differential signals without use of active elements, wherein the resistor or capacitor positions are selectively populated with resistors or capacitors to create different signal paths in different resistor or capacitor configurations and unpopulated resistor positions create open circuits in corresponding signal paths dependent on an application to be provided by the passive switch circuit in the avionics system, and wherein the resistor or capacitor positions are configured such that when populated with resistors or capacitors, unused signal paths are connected to ground and configured to prevent unwanted noise coupling to active signal paths.

In Example 18, the subject matter of Example 17 includes, wherein: the resistor or capacitor positions are arranged with shared landing pads, each shared landing pad is a single conductive pad that is designed to accommodate a resistor or capacitor disposed in different positions on the passive switch circuit to provide the different resistor configurations, and the different resistor or capacitor configurations are configured to provide identical impedances.

In Example 19, the subject matter of Examples 17-18 includes, wherein: the passive switch circuit comprises separate ground vias for the populated resistors to avoid current sharing between different signal paths, and the ground vias are disposed around the passive switch circuit to minimize electromagnetic radiation, including an outer edge of the passive switch circuit.

In Example 20, the subject matter of Examples 17-19 includes, Gbps signals to external test equipment via one of endpoints for testing to avoid adding test points on a printed circuit board that contains the passive switch circuit.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to indicate one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. As indicated herein, although the term “a” is used herein, one or more of the associated elements may be used in different embodiments. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least” the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, the subject matter lies in less than all features of a single disclosed embodiment. Thus, the following claims are hereby incorporated into the Detailed Description, with each claim standing on its own as a separate embodiment.

What is claimed is:

1. A printed circuit board (PCB) for use in an avionics system, the PCB comprising:
a passive switch circuit having resistor or capacitor positions arranged on a printed circuit board configured to selectively route differential signals of at least 25 Gigabits per second (Gbps) between connection points of external circuitry in the avionics system without use of active elements in the passive switch circuit,
wherein the resistor positions are configured to be selectively populated with resistors or capacitors to create different signal paths in different resistor or capacitor configurations and unpopulated resistor or capacitor positions create open circuits in corresponding signal paths dependent on an application to be provided by the passive switch circuit in the avionics system.

2. The PCB of claim 1, wherein:
the resistor or capacitor positions are arranged with shared landing pads,
each shared landing pad is a single conductive pad that is designed to accommodate a resistor or capacitor disposed in different positions on the passive switch circuit to provide the different resistor or capacitor configurations, and
the different resistor or capacitor configurations are configured to provide identical impedances.

3. The PCB of claim 2, wherein the resistor or capacitor positions are configured such that when populated with resistors or capacitors, unused signal paths are connected to ground and configured to reduce noise coupling to active signal paths.

4. The PCB of claim 3, further comprising separate ground vias for the populated resistors or capacitors to mitigate current sharing between different signal paths.

5. The PCB of claim 4, wherein the ground vias are disposed around the passive switch circuit to minimize electromagnetic radiation, including an outer edge of the passive switch circuit.

6. The PCB of claim 1, wherein the resistor or capacitor positions are configured to route signals between a first connector and either a second connector or a third connector dependent on the resistor or capacitor configuration.

7. The PCB of claim 6, wherein:
in a first configuration, a first set of resistor positions is populated with resistors to establish a signal path between the first connector and the second connector, while the third connector is grounded, and
in a second configuration, a second set of resistor positions is populated with resistors to establish a signal path between the first connector and the third connector, while the second connector is grounded.

8. The PCB of claim 1, wherein:
the resistors comprise zero-ohm resistors,
the capacitors comprise 100 nF to 220 nF capacitors, and
a resistor or capacitor configuration used in the passive switch circuit is preconfigured and selected during assembly based on the avionics system.

9. The PCB of claim 1, wherein the resistors have resistance values selected for at least one of impedance matching or signal attenuation, spacing between resistors and ground planes controlled to maintain a constant differential impedance throughout each signal path.

10. A method for providing passive switching in an avionics system, the method comprising:
providing a printed circuit board (PCB) having a passive switch circuit with resistor or capacitor positions arranged to selectively route differential signals of at least 25 Gigabits per second (Gbps) between connection points without use of active elements in the passive switch circuit;
determining a signal routing configuration for the passive switch circuit dependent on an application to be provided by the passive switch circuit in the avionics system;
selecting a set of the resistor or capacitor positions for population based on the determined signal routing configuration; and
populating the selected resistor or capacitor positions with resistors or capacitors while leaving unselected resistor or capacitor positions unpopulated prior to installation in the avionics system.

11. The method of claim 10, further comprising arranging the resistor or capacitor positions using shared landing pads to minimize impedance mismatches and maintain consistent impedance throughout a signal path regardless of which resistor configuration is implemented, each shared landing pad being a single conductive pad that is designed to accommodate a resistor or capacitor disposed in different positions on the passive switch circuit to provide the different resistor configurations, the different resistor or capacitor configurations configured to provide identical impedances.

12. The method of claim 10, further comprising grounding unused signal paths through the populated resistors or capacitors to prevent unwanted noise coupling to active signal paths.

13. The method of claim 12, wherein grounding unused signal paths comprises using separate ground vias to minimize electromagnetic radiation and provide signal return paths.

14. The method of claim 13, wherein the ground vias are disposed around the passive switch circuit to minimize electromagnetic radiation, including an outer edge of the passive switch circuit.

15. The method of claim 10, wherein:
the resistor or capacitor positions are configured to selectively route signals between a first connector and either a second connector or a third connector,
in a first configuration, a first set of resistor positions is populated with resistors to establish a signal path between the first connector and the second connector, while the third connector is grounded, and
in a second configuration, a second set of resistor positions is populated with resistors to establish a signal path between the first connector and the third connector, while the second connector is grounded.

16. The method of claim 10, wherein:
the resistors comprise zero-ohm resistors,
the capacitors comprise 100 nF to 220 nF capacitors, and
a resistor or capacitor configuration used in the passive switch circuit is preconfigured and selected during assembly based on the avionics system.

17. An avionics system comprising:
a transmitter comprising a field-programmable gate array (FPGA) that generates high-speed differential signals of at least 25 Gigabits per second (Gbps);
a receiver comprising an FPGA that processes received high-speed differential signals; and
a passive switch circuit connecting the transmitter and the receiver, the passive switch circuit having resistor or capacitor positions configured to route the high-speed differential signals without use of active elements,
wherein the resistor or capacitor positions are selectively populated with resistors or capacitors to create different signal paths in different resistor or capacitor configurations and unpopulated resistor positions create open circuits in corresponding signal paths dependent on an application to be provided by the passive switch circuit in the avionics system, and
wherein the resistor or capacitor positions are configured such that when populated with resistors or capacitors, unused signal paths are connected to ground and configured to prevent unwanted noise coupling to active signal paths.

18. The avionics system of claim 17, wherein:
the resistor or capacitor positions are arranged with shared landing pads,
each shared landing pad is a single conductive pad that is designed to accommodate a resistor or capacitor disposed in different positions on the passive switch circuit to provide the different resistor configurations, and
the different resistor or capacitor configurations are configured to provide identical impedances.

19. The avionics system of claim 17, wherein:
the passive switch circuit comprises separate ground vias for the populated resistors to avoid current sharing between different signal paths, and the ground vias are disposed around the passive switch circuit to minimize electromagnetic radiation, including an outer edge of the passive switch circuit.

20. The avionics system of claim 17, wherein the passive switch circuit comprises resistors or capacitors enabling routing high-speed 25 Gbps signals to external test equipment via one of endpoints for testing to avoid adding test points on a printed circuit board that contains the passive switch circuit.
